(19) United States
(12) Patent Application Publication
(10) Pub. No.: US 2026/0353988 A1
(43) Pub. Date: Nov. 5, 2026

(54) DISPLAY DEVICE

(71) Applicant: LG Display Co., Ltd., Seoul (KR)

(72) Inventors: Hyekyung Choi, Seoul (KR); UngGi Lee, Paju-si (KR); SeoHui Jung, Goyang-si (KR); Yongbong Lee, Jeju-si (KR); Yujin Lee, Goyang-si (KR)

(73) Assignee: LG Display Co., Ltd., Seoul (KR)

(21) Appl. No.: 19/559,687

(22) Filed: Mar. 6, 2026

(30) Foreign Application Priority Data
Apr. 30, 2025 (KR) 10-2025-0057564

(51) Int. Cl. H10K 59/80; H10K 59/122; H10K 59/131; H10K 102/00

(52) U.S. Cl. CPC H10K 59/874; H10K 59/122; H10K 59/1315; H10K 59/80521; H10K 59/873; H10K 2102/351

(57) ABSTRACT

A display device includes a substrate including a display area and a non-display area, an insulating layer and a planarization layer over the substrate and extending to the non-display area, at least one trench in the non-display area and confined by removing at least one of the insulating layer and the planarization layer, a bank on the planarization layer and extending to the non-display area, an organic layer on the bank, a cathode on the organic layer, a protective layer extending to the non-display area, and an encapsulation structure on the protective layer in which the protective layer extends outward from an end of the encapsulation structure on four sides except for a part of the non-display area, the planarization layer and the bank do not extend outward of the trench, but inside the trench, and effectively suppress oxygen permeation and suppress moisture permeation and enhance moisture permeability.

### CROSS-REFERENCE TO RELATED APPLICATIONS

This application claims the priority of Korean Patent Application No. 10-2025-0057564 filed on Apr. 30, 2025, in the Ministry of Intellectual Property of the Republic of Korea, the disclosure of which is incorporated herein by reference.

### BACKGROUND

### Technical Field

The present disclosure relates to a display device, and more particularly, to a display device capable of preventing moisture permeation and oxygen permeation.

### Discussion of the Related Art

Currently, as it enters a full-fledged information era, the field of display devices that visually display electrical information signals is rapidly developing, and research is being conducted to improve performances, such as thinning, weight reduction, and low power consumption, for various display devices.

Representative display devices include a liquid crystal display (LCD), an electro-wetting display (EWD), and an organic light emitting display (OLED).

Among them, an electroluminescent display device including an organic light emitting display device is a self-emitting display device and does not require a separate light source unlike a liquid crystal display device, and thus may be manufactured to have a light weight and a small thickness. In addition, the electroluminescent display device is advantageous not only in terms of power consumption due to low voltage driving, but also in terms of color implementation, response speed, viewing angle, and contrast ratio, so that it is expected to be used in various fields.

In the electroluminescent display device, a bezel interval having a predetermined level or higher is required to block permeation of moisture and oxygen from the outside and secure long-term reliability. However, in the deposition process of the cathode and the organic film, a shadow area occurs due to a gap formed between the mask and the substrate, which acts as a technical constraint on reducing the bezel to a certain level or less. In addition, as the bezel becomes thinner, the thickness of the cathode and the insulating film also decreases, and such a thin-filmed structure becomes more vulnerable to the penetration of oxygen and moisture from the external environment. As a result, deterioration of the organic light emitting device is accelerated, and there is a problem that dark spot defects may occur.

### SUMMARY

Accordingly, embodiments of the present disclosure are directed to a display device that substantially obviates one or more of the problems due to limitations and disadvantages of the related art.

An aspect of the present disclosure is to provide a display device which blocks moisture and oxygen while reducing a bezel width.

Another aspect of the present disclosure is to provide a display device which improves a reliability life and secures a manufacturing efficiency and a degree of design freedom.

Still another aspect of the present disclosure is to provide a display device capable of preventing a dark spot defect caused by outgas of a planarization layer.

Still another aspect of the present disclosure is that the adhesion between the panel and the adhesive layer is improved to be lifted. It is to provide a display device capable of preventing defects.

Still another aspect of the present disclosure is to provide a display device capable of eliminating the possibility of moisture permeation failure due to metal-metal bonding in a trench.

Still another aspect of the present disclosure is to provide a display device capable of blocking a moisture permeation and oxygen permeation path by increasing a thickness of a protective layer in a tapered portion of a trench.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a display area and a non-display area, an insulating layer and a planarization layer disposed over the substrate and extending to the non-display area, at least one trench disposed in the non-display area and confined by removing at least one of the insulating layer and the planarization layer, a bank disposed on the planarization layer and extending to the non-display area, an organic layer disposed on the bank, a cathode disposed on the organic layer and extending to the trench, a protective layer disposed on the cathode and extending to the non-display area, and an encapsulation structure disposed on the protective layer, in which the protective layer extends outward from an end of the encapsulation structure on four sides excluding a part of one side of the non-display area, and the planarization layer and the bank may not extend outward of the trench, but may be disposed inside the trench.

A display device according to another exemplary embodiment of the present disclosure includes a substrate including a display area and a non-display area having four sides disposed to surround the display area, a first trench disposed over three sides excluding one side of the non-display area and formed by removing a portion of an insulating layer and a planarization layer, a second trench formed by removing the planarization layer and a plurality of open holes formed by removing the planarization layer from the outside of the second trench at one side of the non-display area, wherein the planarization layer does not extend to the outside of the trench, but may be disposed inside the trench.

Other detailed matters of the embodiments are included in the detailed description and the drawings.

According to the present disclosure, by forming a trench in the shadow area generated by the use of the deposition mask, it is possible to effectively reduce the bezel width and suppress the penetration of moisture and oxygen, thereby improving the moisture permeation prevention performance and reliability.

According to the present disclosure, by forming an open hole in which the organic layers of the planarization layer and the bank are removed in the data pad part, the penetration path of oxygen and moisture in the data pad part can be blocked, thereby minimizing the effect of deterioration due to moisture permeation and oxygen permeation and securing long-term reliability of the display device.

According to the present disclosure, by adding a bar trench structure, it is possible to effectively block the penetration of oxygen and moisture from the external environment, thereby preventing the degradation of the organic light emitting element.

In the present disclosure, a trench and a bar trench structure may be formed in an existing manufacturing process without adding a separate process, thereby securing manufacturing efficiency and improving design freedom.

In the present disclosure, the anode layer inside the trench is removed to remove an unnecessary metal-metal bonding structure, thereby suppressing the occurrence of moisture permeation defects.

According to the present disclosure, the planarization layer and the bank outside the non-display area are removed to improve adhesion between the panel and the adhesive layer, thereby preventing lifting defects, and preventing dark spot defects caused by outgassing of the planarization layer.

According to the present disclosure, by extending and disposing the protective layer to the outer portion of the non-display area including the trench, it is possible to increase the thickness of the protective layer in the tapered portion of the trench, thereby effectively blocking the penetration of moisture and oxygen through the tapered portion.

Accordingly, the present disclosure may simultaneously achieve high reliability, manufacturing efficiency, and design freedom while reducing the bezel width.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles.

FIG. 1 is a plan view of a display device according to a first embodiment of the present disclosure.

FIG. 2 is a cross-sectional view of a sub pixel of the display device of FIG. 1.

FIG. 3 is a cross-sectional view taken along the line Ia-Ia′ of FIG. 1.

FIG. 4 is a cross-sectional view taken along the line Ib-Ib′ of FIG. 1.

FIG. 5 is a cross-sectional view taken along the line Ic-Ic′ of FIG. 1.

FIG. 6 is an enlarged view of part A of FIG. 1.

FIG. 7 is a cross-sectional view taken along line A-A′ in FIG. 6.

FIG. 8 is a cross-sectional view taken along line B-B′ in FIG. 6.

FIG. 9 is a plan view of a display device according to a second embodiment of the present disclosure.

FIG. 10 is a cross-sectional view taken along the line IIa-IIa′ of FIG. 9.

FIG. 11 is a cross-sectional view taken along a line IIb-IIb′ of FIG. 9.

FIG. 12 is an enlarged view of part B of FIG. 9.

FIG. 13 is a cross-sectional view taken along the line C-C′ of FIG. 12.

FIG. 14 is a cross-sectional view of a display device according to a third embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to the accompanying drawings.

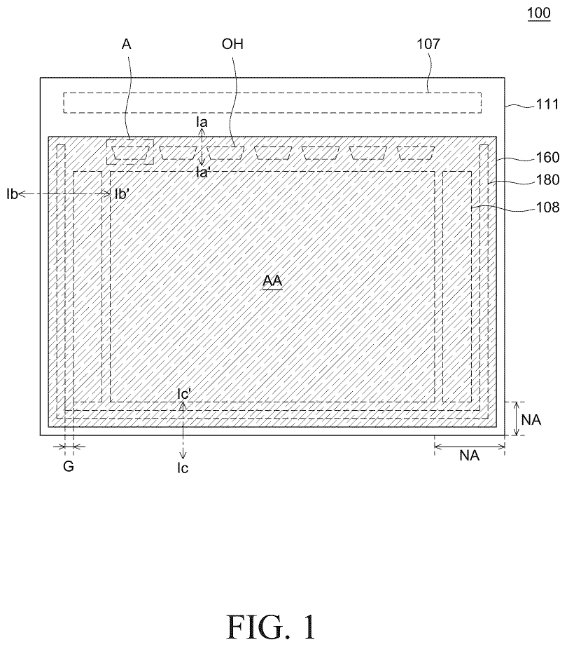

FIG. 1 is a plan view of a display device according to a first embodiment of the present disclosure.

Referring to FIG. 1, a display device 100 according to a first embodiment of the present disclosure may include a substrate 111, an encapsulation substrate 160, and pad parts 107 and 108.

The display device 100 is a device for displaying an image to a user.

In the display device 100, a display element for displaying images, a driving element for driving the display element, and signal lines for transmitting various signals to the display element and the driving element may be disposed. The display element may be differently defined depending on the type of the display device 100, and for example, when the display device 100 is an organic light emitting display device, the display element may be an organic light emitting element including an anode, an organic emission layer, and a cathode. For example, when the display device 100 is a liquid crystal display device, the display element may be a liquid crystal display element.

Hereinafter, even though it is assumed that the display device 100 is an organic light emitting display device, the display device 100 is not limited to the organic light emitting display device.

The display device 100 may include a display area AA and a non-display area NA.

The display area AA is an area in which images are displayed in the display device 100.

In the display area AA, a plurality of sub pixels constituting a plurality of pixels and a circuit for driving the plurality of sub pixels may be disposed. The plurality of sub pixels is minimum units constituting the display area AA, and a display element may be disposed in each of the plurality of sub pixels, and the plurality of sub pixels may constitute a pixel. For example, an organic light emitting element including an anode, an organic emission layer, and a cathode may be disposed in each of the plurality of sub pixels, but is not limited thereto. Further, a circuit for driving the plurality of sub pixels may include a driving element, a line, and the like. For example, the circuit may include a thin film transistor, a storage capacitor, a gate line, a data line, and the like, but is not limited thereto.

The non-display area NA is an area where no image is displayed.

FIG. 1 illustrates that the non-display area NA encloses the display area AA having a rectangular shape. However, the shapes and arrangements of the display area AA and the non-display area NA are not limited to the example illustrated in FIG. 1.

In other words, the display area AA and the non-display area NA may have shapes suitable for the design of an electronic device equipped with the display device 100. For example, an exemplary shape of the display area AA may be a pentagon, a hexagon, a circle, or an oval.

In the non-display area NA, various lines and circuits for driving the organic light emitting element of the display area AA may be disposed. For example, in the non-display area NA, link lines for transmitting signals to the plurality of sub pixels and circuits of the display area AA, driving ICs such as gate driver ICs and data driver ICs or pad parts 107 and 108 may be disposed, but are not limited thereto.

The pad parts 107 and 108 may be disposed to receive a signal from the outside.

The pad parts 107 and 108 may be disposed in the non-display area NA of the display device 100 to be electrically connected to various signal lines and printed circuit boards disposed in the display area AA.

For example, the pad parts 107 and 108 may function to transmit a signal to each of the gate line and the data line, and include a gate pad part 108 to transmit a gate signal to the gate line and a data pad part 107 to transmit a data signal to the data line, but are not limited thereto.

The gate pad part 108 may be disposed on at least one side of the display device 100, for example, in the non-display area NA on the first side, but is not limited thereto. In this case, the first side may mean one of left and right sides of the display device 100 adjacent to the upper and lower sides of the display device 100.

The data pad part 107 may be disposed in the non-display area NA on the other side of the display device 100, for example, the second side, but is not limited thereto. For example, the second side may refer to an upper side of the display device 100, but is not limited thereto.

For example, the data pad part 107 may be electrically connected to a data driver to supply a data voltage to a plurality of data lines. The data driver may receive image data from the timing controller and supply a data voltage to the plurality of data lines to drive the plurality of data lines. The data driver may be implemented by including one or more source driver integrated circuits.

Meanwhile, the gate driver may drive a plurality of gate lines by outputting a scan signal to the plurality of gate lines. For example, the gate driver may sequentially drive the plurality of gate lines by sequentially supplying scan signals to the plurality of gate lines. The gate driver may sequentially supply an on voltage or an off voltage scan signal to the plurality of gate lines under the control of the timing controller.

The gate driver may include a plurality of gate driving circuits. Here, the plurality of gate driving circuits may correspond to the plurality of gate lines, respectively.

Each gate driving circuit may be implemented in a gate-in-panel (GIP) type and embedded in the display device 100. For example, each gate driving circuit may be directly disposed on the gate pad part 108, and in this case, the gate pad part 108 may be referred to as a GIP circuit portion.

Meanwhile, in the display device 100 according to the first exemplary embodiment of the present disclosure, the trench 180 may be provided in the non-display area NA to secure reliability such as prevention of moisture permeation.

The trench 180 may be disposed to surround the display area AA except for the upper side, but is not limited thereto. On the other hand, the open hole OH from which the organic layers of the planarization layer and the bank are removed is formed in the data pad part 107 on the upper side to block the penetration path of oxygen and moisture in the data pad part 107.

Further, in the display device 100 according to the first embodiment of the present disclosure, the GIP circuit portion 108 is disposed inside the trench 180 so as to be spaced apart from the trench 180 at a predetermined interval G, thereby minimizing the effect of moisture permeation on the GIP circuit portion 108.

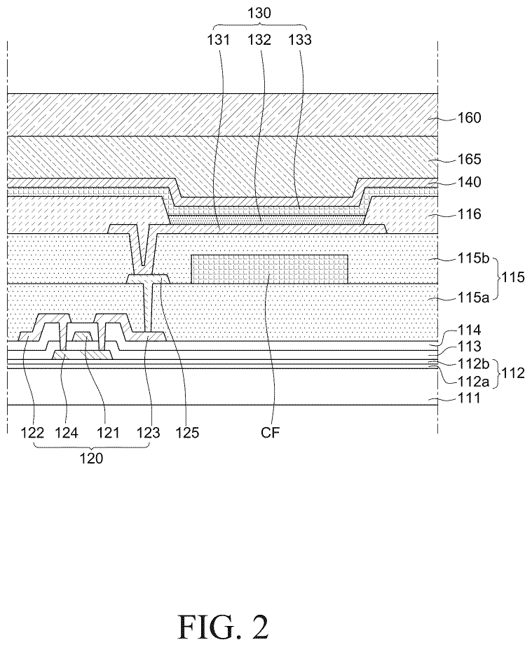

In addition, in the first embodiment of the present disclosure, an unnecessary metal-metal bonding structure is removed by removing the anode layer inside the trench 180. Further, the planarization layer and the bank formed on the outer peripheral portion of the non-display area NA are removed to improve adhesion between the panel and the adhesive layer. In addition, by including the trench 180 and extending and disposing the protective layer to the outer portion of the non-display area NA, the thickness of the protective layer is increased in the tapered portion of the trench 180, which will be described in detail with reference to FIGS. 2 to 5.

FIG. 2 is a cross-sectional view of a sub pixel of the display device of FIG. 1.

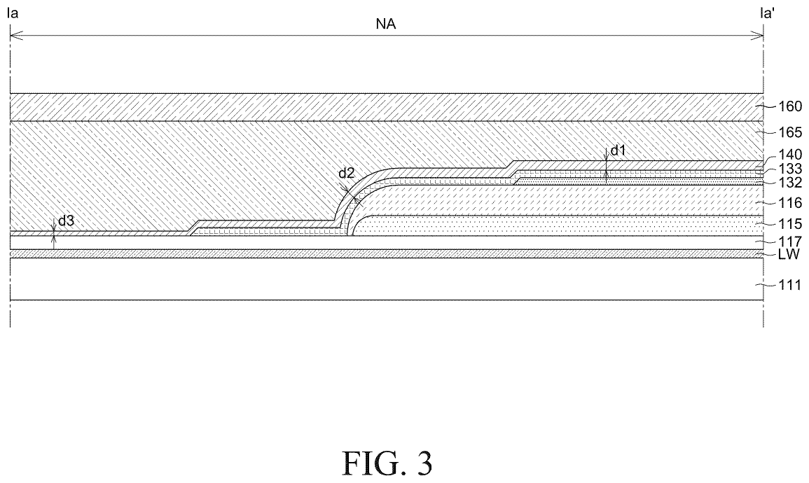

FIG. 3 is a cross-sectional view taken along the line Ia-Ia′ of FIG. 1.

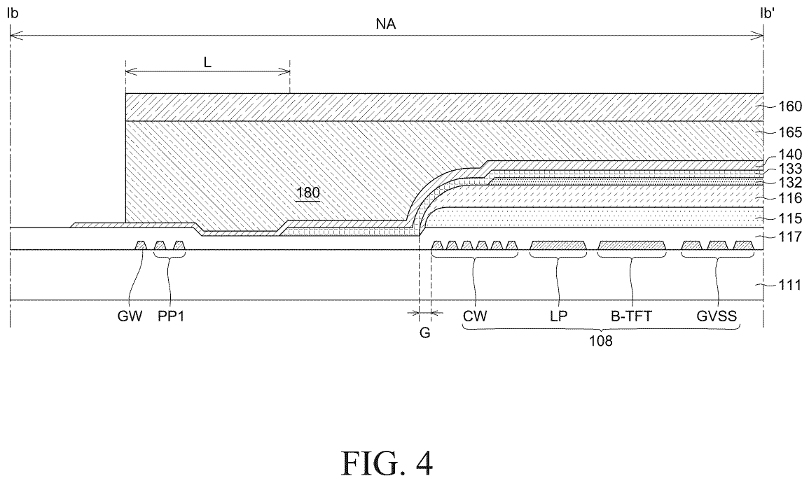

FIG. 4 is a cross-sectional view taken along the line Ib-Ib′ of FIG. 1.

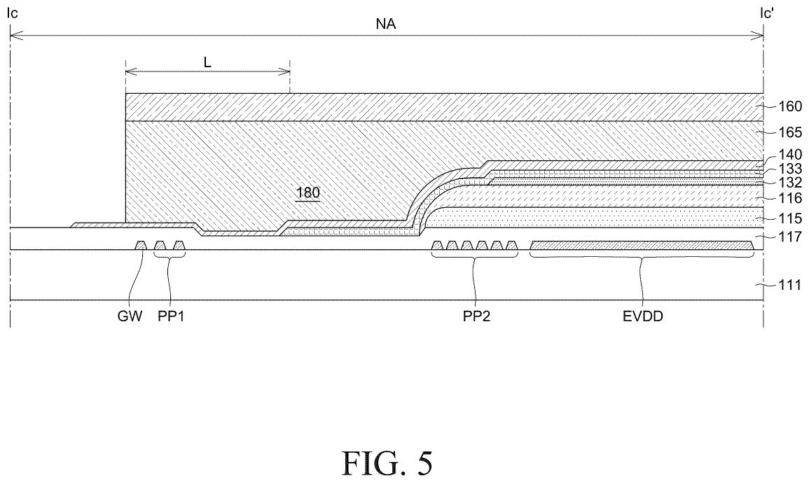

FIG. 5 is a cross-sectional view taken along the line Ic-Ic′ of FIG. 1.

FIG. 3 shows a part of the non-display area NA of the second side in the display device 100 of FIG. 1, and FIG. 4 shows a part of the non-display area NA of the first side in the display device 100 of FIG. 1. FIG. 5 shows a part of the non-display area NA of the third side of the display device 100 of FIG. 1.

For example, the first side may refer to the left side of the display device 100, the second side may refer to the upper side, and the third side may refer to the lower side facing the upper side, but is not limited thereto.

In addition, FIG. 4 schematically illustrates the GIP circuit portion 108 included in the non-display area NA for the convenience of description, and in FIGS. 3 to 5, at least a part of the buffer layer 112, the gate insulating layer 113, and the interlayer insulating layer 114 are illustrated as the insulating layer 117 for the convenience of description.

Referring to FIGS. 2 to 5, in the display device 100 (see FIG. 1) of the first embodiment of the present disclosure, the driving element 120 may be disposed on the substrate 111.

Further, the planarization layer 115 may be disposed on the driving element 120.

Further, the light emitting element 130 electrically connected to the driving element 120 may be disposed on the planarization layer 115, and the protective layer 140 may be disposed on the light emitting element 130.

The adhesive layer 165 and the encapsulation substrate 160 may be sequentially disposed on the protective layer 140. However, the display device 100 according to the first embodiment of the present disclosure is not limited to this laminated structure.

Meanwhile, a trench 180 may be provided at an edge of the non-display area NA between the substrate 111 and the encapsulation substrate 160.

The substrate 111 may be a glass or plastic substrate. In the case of a plastic substrate, a polyimide-based or polycarbonate-based material may be used to have flexibility. In particular, polyimide is a material that can be applied to a high-temperature process and can be coated, so it is widely used as a plastic substrate.

A buffer layer 112 may be disposed on the substrate 111.

Meanwhile, although not illustrated, a light shielding layer may be disposed on the substrate 111 to block light introduced from a lower portion of the substrate 111.

A light shielding layer may be disposed on the substrate 111 at a position where the active layer 124 is to be formed. In particular, it is preferable that the size of the light shielding layer is slightly larger so as to completely cover the active layer 124.

A buffer layer 112 may be disposed on the entire surface of the substrate 111 on which the light shielding layer is formed.

The buffer layer 112 is a layer for protecting various electrodes and lines from impurities such as alkali ions discharged from the substrate 111 or the underlying layers. The buffer layer 112 may have a multilayer structure including a first buffer layer 112a and a second buffer layer 112b, but is not limited thereto. For example, the buffer layer 112 may be made of silicon oxide (SiOx), silicon nitride (SiNx), or a multi-layer thereof.

The buffer layer 112 may delay diffusion of moisture and/or oxygen permeating the substrate 111. In addition, the buffer layer 112 may include a multi-buffer and/or an active buffer.

Meanwhile, in the non-display area NA, various lines and circuits for driving the light emitting element 130 of the display area AA may be disposed. For example, in the non-display area NA, link lines for transmitting signals to the plurality of sub pixels and circuits of the display area AA, driving ICs such as gate driver ICs and data driver ICs or pad parts 107 and 108 may be disposed, but are not limited thereto.

For example, the ground line GW may be disposed on the substrate 111 in the non-display area NA.

The ground line GW may be disposed at the edge of the non-display area NA excluding the upper side.

The ground line GW may be disposed adjacent to the edge of the encapsulation substrate 160.

A first anti-scattering pattern PP1 may be disposed inside the ground line GW.

The link line LW may be disposed above the substrate 111 in a part of the non-display area NA above the substrate 111. For example, the link line LW may be disposed above the substrate 111 in a part of the non-display area NA above which the open hole OH (see FIG. 1) is not disposed.

In the non-display area NA on the left and right sides, the GIP circuit portion 108 may be disposed inside the trench 180.

The GIP circuit portion 108 may include a control signal clock line CW, a logic unit LP, a buffer TFT unit B-TFT, and a power line GVSS, but is not limited thereto.

For example, the trench 180 may be disposed in the order of the control signal clock line CW, the logic unit LP, the buffer TFT unit B-TFT, and the power line GVSS. However, the present disclosure is not limited thereto.

In this case, the control signal clock line CW, the logic unit LP, the buffer TFT unit B-TFT, and the power line GVSS may be configured using a light shielding layer of the display area AA or a material for forming the driving element 120, but the configuration is only one example and is not limited thereto.

Further, in the non-display area NA on the third side, the second anti-scattering pattern PP2 and the second power line EVDD may be disposed inside the trench 180.

For example, the second anti-see-through pattern PP2 and the second power line EVDD may be disposed from the trench 180 in this order, but such a configuration is only an example and the present disclosure is not limited thereto.

The second anti-see-through pattern PP2 and the second power line EVDD may be configured using a material for forming the light shielding layer or the driving element 120 of the display area AA, but such a configuration is only an example, and the present disclosure is not limited thereto.

The driving element 120 may include an active layer 124, a gate insulating layer 113, a gate electrode 121, an interlayer insulating layer 114, a source electrode 122, and a drain electrode 123. Further, the driving element 120 may be electrically connected to the light emitting element 130 through the connection electrode 125 to transmit a current or a signal to the light emitting element 130. In addition to the illustrated top gate structure, the driving element 120 may be applied in various ways, such as a bottom gate structure in which the gate electrode is located below the active layer or a coplanar structure in which the gate electrode, the source electrode, and the drain electrode are disposed on the same plane.

The active layer 124 may be positioned on the buffer layer 112. The active layer 124 may be made of polysilicon (p-Si), and in this case, a predetermined area may be doped with impurities. Further, the active layer 124 may be made of amorphous silicon (a-Si) and may be made of an organic semiconductor material such as pentacene. Further, the active layer 124 may be formed of an oxide semiconductor.

The gate insulating layer 113 may be positioned on the active layer 124. For example, the gate insulating layer 113 may be formed of an insulating inorganic material such as silicon oxide (SiOx) or silicon nitride (SiNx), but is not limited thereto, and may be formed of an insulating organic material in some cases.

The gate electrode 121 may be positioned on the gate insulating layer 113. For example, the gate electrode 121 may be made of various conductive materials, such as magnesium (Mg), aluminum (Al), nickel (Ni), chromium (Cr), molybdenum (Mo), tungsten (W), gold (Au), or an alloy thereof.

The interlayer insulating layer 114 may be positioned on the gate electrode 121. For example, the interlayer insulating layer 114 may be formed of an insulating material such as silicon oxide (SiOx) or silicon nitride (SiNx), or an insulating organic material.

A contact hole through which the source and drain areas are exposed may be formed by selective removal of the gate insulating layer 113 and the interlayer insulating layer 114. The source electrode 122 and the drain electrode 123 may be formed on the interlayer insulating layer 114 in a single layer or a multi-layered structure using an electrode material.

If necessary, an additional protective layer made of an inorganic insulating material may be formed to cover the source electrode 122 and the drain electrode 123.

Meanwhile, at least some of the buffer layer 112, the gate insulating layer 113, and the interlayer insulating layer 114, i.e., the insulating layer 117, may extend to the non-display area NA.

The planarization layer 115 may be disposed on the driving element 120 configured as described above.

The planarization layer 115 may have a multilayer structure including at least two layers. For example, referring to FIG. 2, the planarization layer 115 may include a first planarization layer 115a and a second planarization layer 115b, but is not limited thereto.

For example, the first planarization layer 115a is disposed to cover the driving element 120 and may be disposed to expose a part of the source electrode 122 or the drain electrode 123 of the driving element 120.

The planarization layer 115 may extend to a partial area of the non-display area NA.

The planarization layer 115 may be an overcoat layer, but is not limited thereto.

A connection electrode 125 for electrically connecting the driving element 120 and the light emitting element 130 may be disposed on the first planarization layer 115a.

Further, a second planarization layer 115b may be disposed on the first planarization layer 115a and the connection electrode 125.

The second planarization layer 115b may be formed to expose a part of the connection electrode 125. Further, the drain electrode 123 of the driving element 120 and the anode 131 of the light emitting element 130 may be electrically connected by the connection electrode 125. However, the present disclosure is not limited thereto, and the anode may be directly electrically connected to the drain electrode without a connection electrode.

In this case, the light emitting element 130 may be configured such that the anode 131, a plurality of organic layers 132, and the cathode 133 are sequentially disposed. That is, the light emitting element 130 may include an anode 131 disposed on the planarization layer 115, an organic layer 132 disposed on the anode 131, and a cathode 133 disposed on the organic layer 132.

The display device 100 may be implemented in a top emission type or a bottom emission type. In the top emission method, a reflective layer made of an opaque conductive material having high reflectivity, for example, silver (Ag), aluminum (Al), gold (Au), molybdenum (Mo), tungsten (W), chromium (Cr), or an alloy thereof, may be added under the anode 131 so that light emitted from the organic layer 132 is reflected by the anode 131 and directed upward, that is, in the direction of the cathode 133 at the top. Conversely, in the case of the bottom emission type, the anode 131 may be made of only a transparent conductive material such as indium tin oxide (ITO), indium zinc oxide (IZO), indium gallium zinc oxide (IGZO). Hereinafter, the description will be made on the assumption that the display device 100 of the present disclosure is a bottom emission type. However, the present disclosure is not limited thereto.

The bank 116 may be disposed on the planarization layer 115 in the remaining area except for the emission area. That is, the bank 116 has a bank hole exposing the anode 131 corresponding to the emission area. The bank 116 may be made of an inorganic insulating material such as silicon nitride (SiNx) or silicon oxide (SiOx), or an organic insulating material such as BCB, acrylic resin, or imide resin.

The bank 116 may extend to a partial area of the non-display area NA.

The organic layer 132 may be disposed on the anode 131 exposed by the bank 116. The organic layer 132 may include an emission layer, an electron injection layer, an electron transport layer, a hole transport layer, a hole injection layer, and the like.

The organic layer 132 may extend to a partial area of the non-display area NA.

The cathode 133 may be disposed on the organic layer 132.

In the case of the top emission type, the cathode 133 may include a transparent conductive material. For example, the cathode 133 may be formed of indium tin oxide (ITO), indium zinc oxide (IZO), indium gallium zinc oxide (IGZO), or the like. In the case of the bottom emission type, the cathode 133 may include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 133 may be configured by laminating a layer made of a transparent conductive material such as indium tin oxide (ITO), indium zinc oxide (IZO), indium gallium zinc oxide (IGZO), and a layer made of a metal material such as gold (Au), silver (Ag) aluminum (Al), molybdenum (Mo), magnesium (Mg), palladium (Pd), copper (Cu), or an alloy thereof, but is not limited thereto.

The cathode 133 may extend to a partial area of the non-display area NA.

Although not illustrated, a capping layer may be disposed on the cathode 133. The capping layer may be formed of a material having a high refractive index and a high light absorption rate to reduce diffused reflection of external light.

The protective layer 140 may be disposed on the light emitting element 130 configured as described above.

The protective layer 140 may be an inorganic layer, and in this case, may be made of silicon oxide (SiOx), silicon nitride (SiNx), or a multi-layer thereof.

The protective layer 140 may extend to a partial area of the non-display area NA.

The adhesive layer 165 and the encapsulation substrate 160 may be disposed on the protective layer 140.

However, the present disclosure is not limited thereto, and an encapsulation structure of a multilayer structure composed of a sealing member and a reinforcing substrate may be disposed on the protective layer 140.

The adhesive layer 165 may be disposed between the protective layer 140 and the encapsulation substrate 160.

For example, the adhesive layer 165 may serve to delay lateral moisture permeation.

For example, the adhesive layer 165 may further include a moisture absorbent such as a getter in addition to isobutyl rubber resin. The moisture absorbent may include calcium oxide.

The desiccant may be particles having hygroscopicity and absorb moisture and oxygen from the outside to minimize the penetration of moisture and oxygen into the display area AA.

The encapsulation substrate 160 may be disposed on the adhesive layer 165.

The encapsulation substrate 160, together with the adhesive layer 165, may protect the light emitting element 130 from external moisture, oxygen, impact, and the like.

For example, the encapsulation substrate 160 may serve to prevent front moisture permeation.

For example, the encapsulation substrate 160 may be made of stainless steel (SUS) or Invar, but is not limited thereto.

In the non-display area NA, the insulating layer 117 including at least some of the buffer layer 112, the gate insulating layer 113, and the interlayer insulating layer 114 may extend to the end of the substrate 111.

Further, the planarization layer 115 may extend to a part of the non-display area NA. For example, the planarization layer 115 may extend to the non-display area NA to the inside of the trench 180, but is not limited thereto.

Meanwhile, in the display device, a minimum bezel distance is required to secure reliability such as prevention of moisture permeation. In addition, in accordance with the demand for slimming of the display device, the demand for slimming is also increased for the non-display area except the display area in which an image is displayed, but a shadow area is generated due to the gap between the mask and the substrate during deposition of the cathode and the organic layer, and thus there is a limitation to reduction the bezel width.

Accordingly, in the first embodiment of the present disclosure, a trench 180 in which the planarization layer 115 made of an organic layer and the insulating layer 117 having a partial thickness are removed is disposed in the shadow area in the non-display area NA.

The trench 180 is an area from which the organic layer is removed, and serves to block a path through which moisture penetrates along the organic layer to delay moisture penetration from the side surface.

In addition, the total bezel width may be reduced by converting the existing shadow area into the reliable bezel area L. The reliability bezel area L may be defined as an area from an end of the encapsulation substrate 160 to an end of the cathode 133.

The trench 180 may be formed over the non-display area NA of the left, right, and lower sides excluding the upper side in which the data pad part 107 is disposed among the four side portions of the display device 100 (see FIG. 1), but is not limited thereto. In this case, for example, the trench 180 may be formed by removing a part of the thickness of the insulating layer 117 and the planarization layer 115 in the shadow area NA through laser melting. Accordingly, the reliability bezel area L may be expanded, and the bezel width may be reduced by the added reliability bezel area L. The trench 180 may expose at least some of the buffer layer 112, the gate insulating layer 113, and the interlayer insulating layer 114.

For example, the trench 180 may have a predetermined width to prevent deterioration in moisture permeation performance regardless of a position where the cathode 133 is formed in consideration of a process error and a margin.

Meanwhile, the first embodiment of the present disclosure is characterized in that the planarization layer 115 and the bank 116 outside the outer portion of the non-display area NA, that is, the trench 180, are completely removed. Accordingly, adhesion between the panel and the adhesive layer 165 is improved, thereby preventing lifting defects that may occur in an outer portion of the non-display area NA, and preventing dark spot defects caused by outgassing from the planarization layer 115. This is because the adhesive force between the adhesive layer 165 and the insulating layer 117 is stronger than that between the adhesive layer 165 and the planarization layer 115, and encapsulation performance may deteriorate due to panel lifting when adhesion decreases.

In addition, the first embodiment of the present disclosure is characterized in that the anode layer inside the trench 180 is removed. That is, the anode layer made of a material constituting the anode 131 (see FIG. 2) is not disposed in the trench 180, and the cathode 133 may be disposed directly on the insulating layer 117 exposed in the trench 180. Accordingly, the unnecessary metal-metal bonding structure inside the trench 180 may be removed, thereby preventing corrosion due to the galvanic phenomenon and preventing the occurrence of moisture permeation defects.

Further, in the first embodiment of the present disclosure, the bank 116 is disposed inside the trench 180, and the bank 116 is removed outside the trench 180. Accordingly, the water transfer velocity (WTV) may be suppressed.

The side portion of the trench 180 may be formed to have a predetermined taper. For example, the side portion of the trench 180 may have a gentle taper of about 40 degrees or less. Due to this gentle taper shape, the thickness of the cathode 133 deposited thereon can be secured to about 1,000 Å or more.

Meanwhile, in the non-display area NA, the organic layer 132 may be disposed on the bank 116.

The organic layer 132 may extend to the non-display area NA, and an edge thereof may be formed to be disposed inside the edge of the bank 116, but is not limited thereto.

In the non-display area NA, the cathode 133 may be disposed on the organic layer 132.

The cathode 133 may extend into the trench 180 to surround side surfaces of the planarization layer 115 and the bank 116, but is not limited thereto.

The cathode 133 may be in contact with the exposed top surface of the insulating layer 117.

Meanwhile, the display device 100 according to the first embodiment of the present disclosure configured as described above is characterized in that the GIP circuit portion 108 is disposed inside the trench 180.

The first embodiment of the present disclosure is characterized in that the trench 180 is disposed at the edge of the non-display area NA, and the GIP circuit portion 108 is disposed inside the trench 180 so as to be spaced apart from the trench 180 at a predetermined interval G.

In the first configuration of the present disclosure, the main line (e.g., the second power line EVDD) may be rearranged into the inside of the trench 180. The second power line EVDD may be a line for applying a high potential driving voltage to the anode 131.

In the first embodiment of the present disclosure, the cathode 133 may extend into the trench 180 to seal the GIP circuit portion 108.

Accordingly, the present disclosure may minimize the effect of moisture permeation, thereby dramatically improving the stability and durability of the GIP circuit portion 108. Accordingly, it is possible to improve the reliability of the display device 100.

Meanwhile, in the first embodiment of the present disclosure, the protective layer 140 is disposed to extend to an outer portion of the non-display area NA including the trench 180. By extending the protective layer 140 as described above, a sufficient thickness may be ensured even in the tapered portion of the trench 180, and as a result, the penetration of moisture and oxygen through the tapered portion may be more effectively blocked, thereby improving the reliability of the display device 100.

In this case, the protective layer 140 may extend to cover the cathode 133 and the trench 180. For example, the protective layer 140 may extend outward from ends of the adhesive layer 165 and the encapsulation structure of the encapsulation substrate 160.

As described above, in the first embodiment of the present disclosure, the protective layer 140 is formed by extending to the outer area of the encapsulation structure. This is to increase the thickness of the protective layer 140 in the taper of the trench 180 as the shadow range of the protective layer 140 increases. Accordingly, it is possible to enhance the performance of the encapsulation structure by securing the thickness of the protective layer 140 in the taper. In particular, since the taper of the trench 180 is an area that may be a main path from the viewpoint of preventing the penetration of moisture and oxygen in the panel, it is important to secure a sufficient thickness of the cathode 133 and the protective layer 140 in this area. According to the first embodiment of the present disclosure, it is possible to further improve the reliability of the display device 100 by effectively blocking the penetration of moisture and oxygen through the taper of the trench 180.

For example, the protective layer 140 may be made of an inorganic insulating material.

The protective layer 140 may delay the penetration of moisture from the top and suppress the occurrence of defects due to external impact or foreign substances.

The protective layer 140 may be made of silicon oxide (SiOx), silicon nitride (SiNx), or a multi-layered structure thereof to delay the penetration of moisture, but is not limited thereto.

For example, when the protective layer 140 is deposited to a first thickness d1 of about 400 nm, the protective layer 140 is formed by extending to the outside of the encapsulation structure. Therefore, even though the protective layer 140 has a third thickness d3 of 100 nm or less outside the non-display area NA, the taper of the trench 180 may secure a second thickness d2 of about 200 nm to 300 nm.

For example, the protective layer 140 may have a thickness of 50% to 75% of a thickness in the display area AA in the taper of the trench 180.

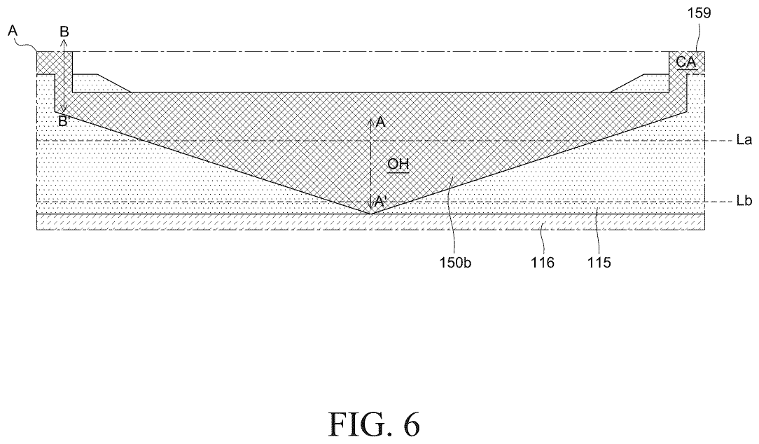

Meanwhile, in the display device 100 according to the first embodiment of the present disclosure, an open hole OH in which the organic layers of the planarization layer 115 and the bank 116 are removed is formed in the data pad part 107 on the upper side in which the trench 180 is not disposed. Therefore, the penetration path of oxygen and moisture in the data pad part 107 may be further blocked. Therefore, it is possible to minimize the effects of moisture and oxygen permeation and further secure the reliability of the display device 100, which will be described in detail with reference to FIGS. 6 to 8.

FIG. 6 is an enlarged view of part A of FIG. 1.

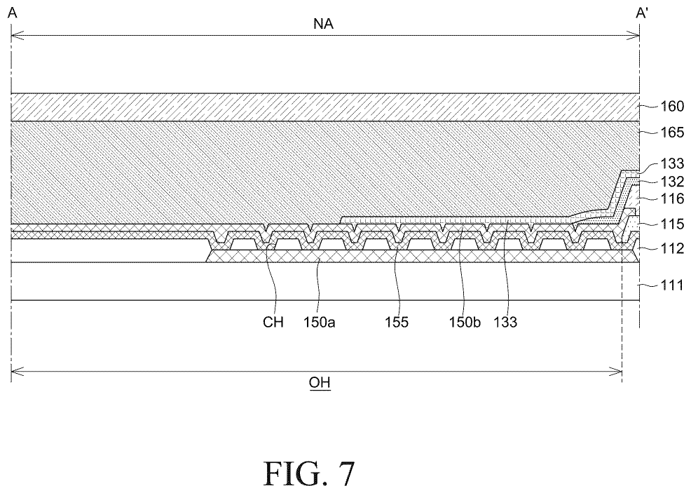

FIG. 7 is a cross-sectional view taken along line A-A′ in FIG. 6.

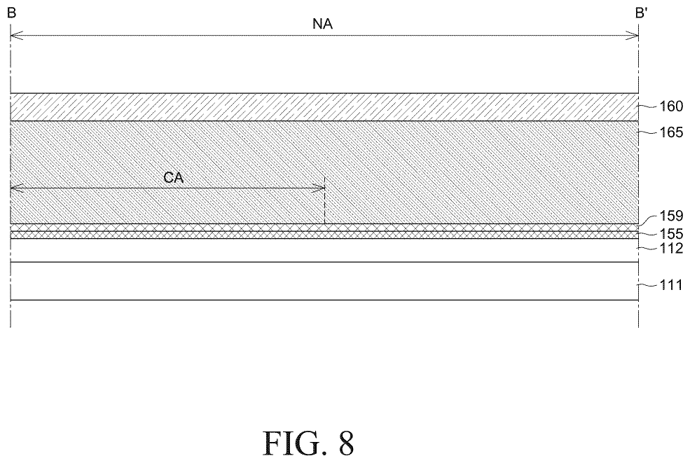

FIG. 8 is a cross-sectional view taken along line B-B′ in FIG. 6.

FIGS. 6 to 8 are plan and cross-sectional view illustrating a part of the non-display area NA on the second side including the open hole OH, that is, on the upper side. In this case, for convenience, in FIG. 6, components above the bank 116 are omitted.

Referring to FIGS. 6 to 8, the first line 150a may be disposed on the substrate 111 in the upper non-display area NA.

The first line 150a may be configured using a material for forming a light shielding layer of the display area AA, but this configuration is only an example and is not limited thereto.

The first line 150a may be connected to the low potential driving voltage line 155 to serve to lower the overall resistance. In addition, the first line 150a may serve to transmit the low potential driving voltage supplied through the connection electrode 159 to the low potential driving voltage line 155.

The buffer layer 112 may be disposed on the first line 150a.

The buffer layer 112 may be patterned in an island shape in an area where the open hole OH is located, but is not limited thereto. A plurality of contact holes CH are formed in the buffer layer 112 to expose a top surface of the first line 150a located therebelow.

The low potential driving voltage line 155 may be disposed on the buffer layer 112.

The low potential driving voltage line 155 may be electrically connected to the first line 150a through the contact hole CH.

The low potential driving voltage line 155 may receive a low potential driving voltage through the first line 150a.

The low potential driving voltage line 155 may be configured using a material for forming the driving element 120 (see FIG. 2) in the display area AA (see FIG. 2), for example, a material for forming the gate electrode 121 (see FIG. 2), but this is only an example and is not limited thereto.

The planarization layer 115 may be disposed on the low potential driving voltage line 155.

The first embodiment of the present disclosure is characterized in that the planarization layer 115 and the bank 116 are removed from a partial area of the data pad part 107 (see FIG. 1) to form the open hole OH. The area in which the open hole OH is formed, that is, the open hole OH area is an area in which the planarization layer 115 and the bank 116 are removed, and may be defined as an area in which line and electrodes supplying and transmitting a low potential driving voltage, that is, the first line 150a, the low potential driving voltage line 155, and the second line 150b are connected to each other.

The open hole OH area is an area in which the planarization layer 115 and the bank 116 are not disposed, and may have a structural shape and function similar to that of the trench 180 (see FIGS. 4-5). In addition, the open hole OH area is designed to secure an electrical connection between the first line 150a, the low potential driving voltage line 155, and the second line 150b, and since the planarization layer 115 and the bank 116 are not present, robustness against the penetration of moisture and oxygen may be ensured. Accordingly, it is possible to prevent defects related to moisture and oxygen permeation in the corresponding area.

As described above, in the first embodiment of the present disclosure, at least one trench 180 is formed to be connected along the left, right, and lower sides to surround the display area AA, and a plurality of open holes OH are formed on the upper side to effectively reduce the bezel width and suppress the penetration of moisture and oxygen at the same time. Accordingly, it is possible to improve the overall moisture permeation prevention performance and the reliability of the display device.

Further, in the first embodiment of the present disclosure, like the outside of the trench, the planarization layer 115 and the bank 116 are completely removed outside the open hole OH.

For example, the open hole OH may have an inverted triangle or an inverted trapezoidal shape in which the lower side is narrowed, but is not limited to this shape.

Meanwhile, the second line 150b may be disposed in the open hole OH.

The connection electrode 159 may be disposed on the low potential driving voltage line 155 in the connection unit CA, which receives the low potential driving voltage from the data pad part 107.

The second line 150b and the connection electrode 159 may be configured using a material for forming the anode 131 (see FIG. 2) of the display area AA, but such a configuration is only an example and is not limited thereto.

For example, the second line 150b may be disposed to extend on a side surface and an upper portion of the planarization layer 115, including the inside of the open hole OH.

The second line 150b may be connected to the low potential driving voltage line 155 and serve to lower the overall resistance. The second line 150b may serve to transmit the low potential driving voltage supplied through the low potential driving voltage line 155 to the cathode 133 as a low potential supply.

Further, the connection electrode 159 may be connected to the low potential driving voltage line 155 to serve to transmit the low potential driving voltage supplied through the data pad part 107 to the low potential driving voltage line 155 and the cathode 133.

For example, the connection electrode 159 may be disposed at both upper ends of the open hole OH, but is not limited thereto. The connection electrode 159 may be integrally formed with the second line 150b, but is not limited thereto.

In the upper non-display area NA, the bank 116 may not be formed in a partial area of the upper end including the open hole OH and the connection part CA.

The bank 116 may be disposed to cover a part of the planarization layer 115 and a part of the second line 150b.

For example, the bank 116 may not be disposed in an area outside the open hole OH.

As described above, in the first embodiment of the present disclosure, the planarization layer 115 and the bank 116 in an area including and surrounding the open hole OH are completely removed to more effectively suppress the moisture penetration and thus further improve the reliability of the display device 100.

The organic layer 132 may be disposed on the bank 116 in the non-display area NA above the bank.

The organic layer 132 may extend into the open hole OH to cover a part of the second line 150b in the open hole OH (see the Lb line of FIG. 6), but is not limited thereto.

In the upper non-display area NA, the cathode 133 may be disposed on the organic layer 132.

The cathode 133 may extend into the open hole OH so as to cover parts of the top surfaces of the organic layer 132 and the second line 150b in the open hole OH (see the line La of FIG. 6), but the present disclosure is not limited thereto.

The cathode 133 may be in contact with the exposed top surface of the second line 150b and thus may receive a low potential driving voltage from the second line 150b.

The encapsulation substrate 160 may be disposed on the cathode 133 via an adhesive layer 165.

As described above, in the first embodiment of the present disclosure, a plurality of open holes OH in which the organic layers of the planarization layer 115 and the bank 116 are removed are formed in the data pad part 107 on the upper side in which the trench 180 is not disposed, such that the penetration path of oxygen and moisture in the data pad part 107 may be blocked, thereby minimizing deterioration due to moisture and oxygen permeation and further securing the reliability of the display device 100.

Meanwhile, in the present disclosure, a bar trench may be additionally disposed inside the trench, which will be described in detail with reference to the drawings.

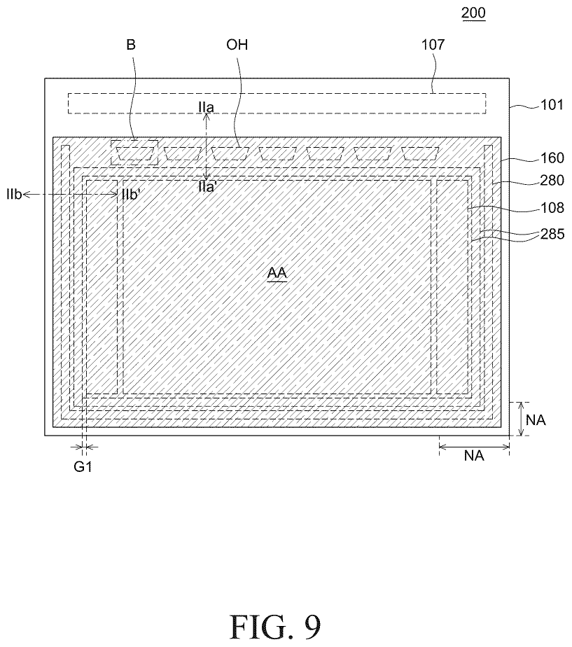

FIG. 9 is a plan view of a display device according to a second embodiment of the present disclosure.

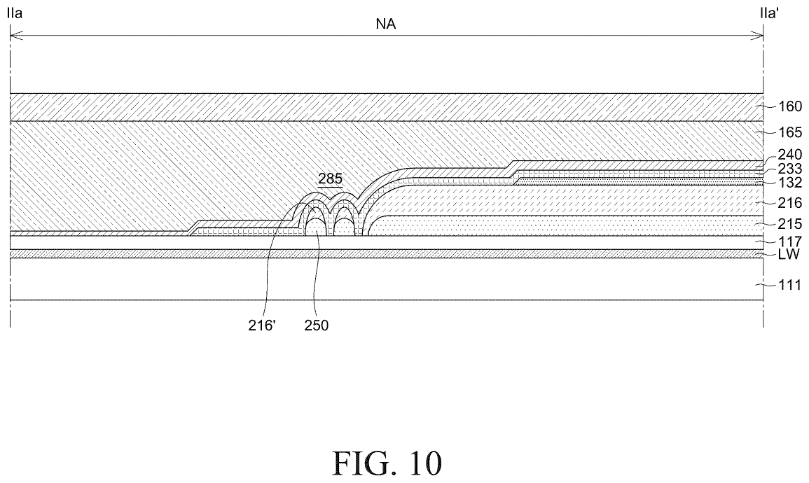

FIG. 10 is a cross-sectional view taken along the line IIa-IIa′ of FIG. 9.

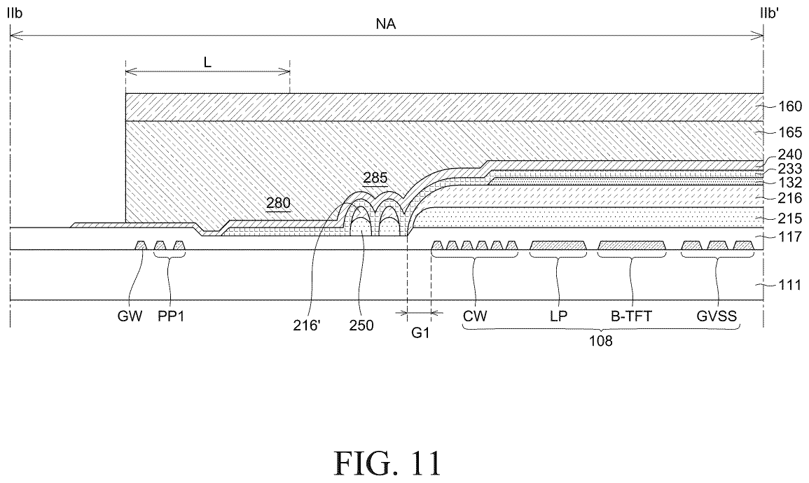

FIG. 11 is a cross-sectional view taken along a line IIb-IIb′ of FIG. 9.

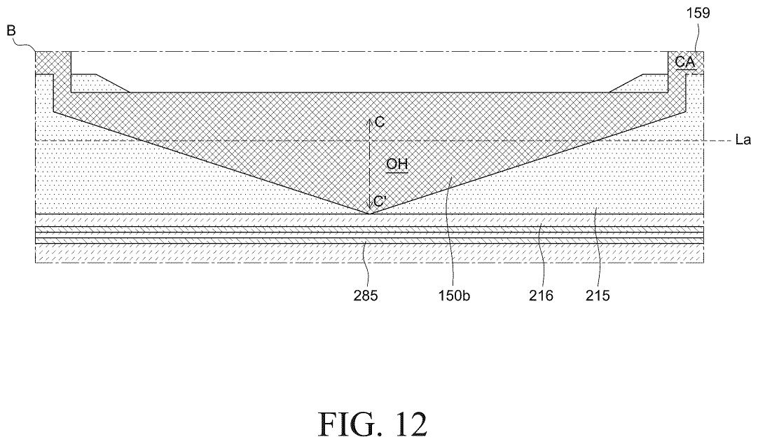

FIG. 12 is an enlarged view of part B of FIG. 9.

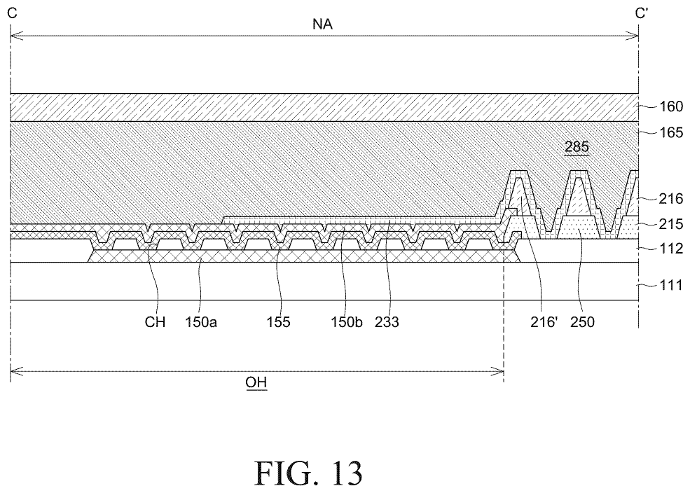

FIG. 13 is a cross-sectional view taken along the line C-C′ of FIG. 12.

The second embodiment of FIGS. 9 to 13 has a different trench configuration 280 and 285 than the first embodiment of FIGS. 1 to 8 described above, and the other configurations are substantially the same, so that a redundant description will be omitted. The same components will be denoted by the same reference numerals. Hereinafter, description of components denoted by the same reference numerals may refer to FIGS. 1 to 8.

FIG. 10 illustrates a part of the non-display area NA of the second side of the display device 200 of FIG. 9, and FIG. 11 illustrates a part of the non-display area NA of the first side of the display device 200 of FIG. 9.

In FIG. 11, for the convenience of description, the GIP circuit portion 108 in the non-display area NA is schematically illustrated. Further, in FIGS. 10 and 11, for convenience, at least some of the buffer layer, the gate insulating layer, and the interlayer insulating layer are illustrated as the insulating layer 117.

FIGS. 12 and 13 are a plan view and a cross-sectional view illustrating a part of the non-display area NA on the second side including the open hole OH, that is, on the upper side. In this case, in FIG. 12, components above the bank 216 are omitted for convenience.

First, referring to FIGS. 9 to 11, in the display device 200 according to the second exemplary embodiment of the present disclosure, a planarization layer 215 may be disposed on the substrate 111.

A ground line GW may be disposed on the substrate 111 in the non-display area NA excluding the upper side.

A first anti-scattering pattern PP1 may be disposed inside the ground line GW.

The link line LW may be disposed above the substrate 111 in a part of the non-display area NA in which the open hole OH (see FIG. 12) is not disposed.

In the non-display area NA on the left and right sides of the second exemplary embodiment of the present disclosure, the GIP circuit portion 108 may be disposed inside the trenches 280 and 285.

The GIP circuit portion 108 may include a control signal clock line CW, a logic unit LP, a buffer TFT unit B-TFT, and a power line GVSS, but is not limited thereto.

A bank 216 may be formed on the planarization layer 215 in the remaining area except for the emission area.

The planarization layer 215 and the bank 216 may extend to a partial area of the non-display area NA.

Meanwhile, in the second exemplary embodiment of the present disclosure, a plurality of trenches 280 and 285 are disposed in the shadow area in the non-display area NA.

The trenches 280 and 285 may include a first trench 280 and a plurality of second trenches 285.

The first trench 280 may be formed over the non-display area NA of the left, right, and lower sides excluding the upper side where the data pad part 107 is disposed, among the four side portions of the display device 200 (see FIG. 9), but is not limited thereto. In this case, for example, the first trench 280 may be formed by removing the planarization layer 215 of the non-display area NA and the insulating layer 117 having a partial thickness. Accordingly, for example, the first trench 280 may expose at least some of the buffer layer, the gate insulating layer, and the interlayer insulating layer.

The second trench 285 may be formed along the four side portions of the display device 200, that is, the non-display areas NA above, left, right, and lower sides (see FIG. 9), but is not limited thereto. In this case, for example, the second trench 285 may be formed by removing a portion of the planarization layer 215 of the non-display area NA. Further, for example, the second trench 285 may expose at least some of the buffer layer, the gate insulating layer, and the interlayer insulating layer.

A plurality of second trenches 285 may be disposed.

The first trench 280 may have a width greater than that of the second trench 285. For example, the first trench 280 may be referred to as an OC hole, and the second trench 285 may be referred to as a bar trench.

For example, a plurality of dams 250 may be disposed between the second trenches 285.

For example, the plurality of dams 250 may be disposed between the first trench 280 and the second trench 285 and between the second trench 285 and another second trench 285, but is not limited thereto.

The dam 250 may be configured as a planarization layer 215, but is not limited thereto.

The dam 250 may have a smaller height than the surrounding planarization layer 215, but is not limited thereto.

The second embodiment of the present disclosure is characterized in that the planarization layer 215 and the bank 216 outside the outer portion of the non-display area NA, that is, outside the first trench 280, are completely removed.

In addition, the second embodiment of the present disclosure is characterized in that the anode layer inside the first trench 280 and the second trench 285 is removed. As described above, as the anode layer on the dam 250 is removed, a phenomenon in which pixels are contracted due to fine particle vapor generated in the planarization layer material may be prevented in advance. That is, by forming an open structure from which the anode layer is removed on the dam 250, fine particle vapor generated after the planarization layer process is efficiently discharged through the open area, thereby preventing deformation of the light emitting element and occurrence of a dark spot defect.

Further, according to the second embodiment of the present disclosure, the side portion of the trench (e.g., the first trench 280) may have a gentle taper of about 40 degrees or less.

Meanwhile, an outer bank 216′ separated from the bank 216 may be disposed in the second trench 285.

For example, the outer bank 216′ has an island shape and may be disposed on the top surface of the dam 250.

A plurality of outer banks 216′ may be formed.

Meanwhile, in the non-display area NA, the organic layer 132 may be disposed on the bank 216.

The organic layer 132 extends to the non-display area NA, and its edge may be disposed further inward than the edge of the bank 216, but is not limited thereto.

In the non-display area NA, the cathode 233 may be disposed on the organic layer 132.

For example, except for a part of the non-display area NA on the upper side, the cathode 233 may extend into the first trench 280 to cover the outer bank 216′ and the second trench 285. On the other hand, in a part of the non-display area NA on the upper side, in which the open hole OH is not disposed, the cathode 233 may extend in the non-display area NA to cover the outer bank 216′ and the second trench 285.

The cathode 233 may be in contact with the exposed top surface of the insulating layer 117.

Further, the protective layer 240 may extend to the outside of the non-display area NA so as to cover the cathode 233. For example, the protective layer 240 may extend outward from ends of the encapsulation structures of the adhesive layer 165 and the encapsulation substrate 160.

The encapsulation substrate 160 may be disposed on the protective layer 240 via an adhesive layer 165.

Meanwhile, the display device 200 according to the second exemplary embodiment of the present disclosure configured as described above is characterized in that the GIP circuit portion 108 is disposed inside the second trench 285.

The second embodiment of the present disclosure is characterized in that the first trench 280 and the plurality of second trenches 285 are disposed at the edge of the non-display area NA, and the GIP circuit portion 108 is disposed inside the second trench 285 so as to be spaced apart from the innermost second trench 285 at a predetermined interval G1.

As described above, in the second exemplary embodiment of the present disclosure, a plurality of second trenches 285 are additionally disposed in the first trench 280 to further delay the moisture penetration rate to the side surface of the display device 200. Further, in the second exemplary embodiment of the present disclosure, the GIP circuit portion 108 is disposed inside the second trench 285 provided inside more than the first trench 280 to more effectively suppress the penetration of moisture or oxygen.

Next, referring to FIGS. 12 and 13, the first line 150a may be disposed on the substrate 111 in the non-display area NA.

The buffer layer 112 may be disposed on the first line 150a.

The low potential driving voltage line 155 may be disposed on the buffer layer 112.

The low potential driving voltage line 155 may be electrically connected to the first line 150a through the contact hole CH.

A planarization layer 215 may be disposed on the low potential driving voltage line 155.

In the second exemplary embodiment of the present disclosure, the planarization layer 215 and the bank 216 may be removed from a partial area of the data pad part 107 (see FIG. 9) to form the open hole OH.

In addition, the second embodiment of the present disclosure is characterized in that the planarization layer 215 and the bank 216 are completely removed even outside the open hole OH, as in the case outside the trench.

The second line 150b may be disposed in the open hole OH.

Further, a connection electrode 159 may be disposed in the connection unit CA.

In the second exemplary embodiment of the present disclosure, the second trench 285 may be disposed in the shadow area in the upper non-display area NA.

For example, a plurality of dams 250 may be disposed between the second trenches 285.

An outer bank 216′ may be disposed in the second trench 285 in the upper non-display area NA.

The outer bank 216′ may be separated from the bank 216. That is, for example, an outer bank 216′ separated from the bank 216 in an island shape may be disposed outside the bank 216.

In the non-display area NA on the upper side, the cathode 233 may be disposed on the bank 216 and the outer bank 216′.

For example, the cathode 233 may extend into the open hole OH so as to cover parts of the top surfaces of the outer bank 216′ and the second line 150b in the second trench 285 and the open hole OH (see the La line in FIG. 12), but is not limited thereto.

The encapsulation substrate 160 may be disposed on the cathode 233 via an adhesive layer 165.

Meanwhile, the present disclosure may further include an oxygen getter in the adhesive layer, which will be described in detail with reference to the drawings.

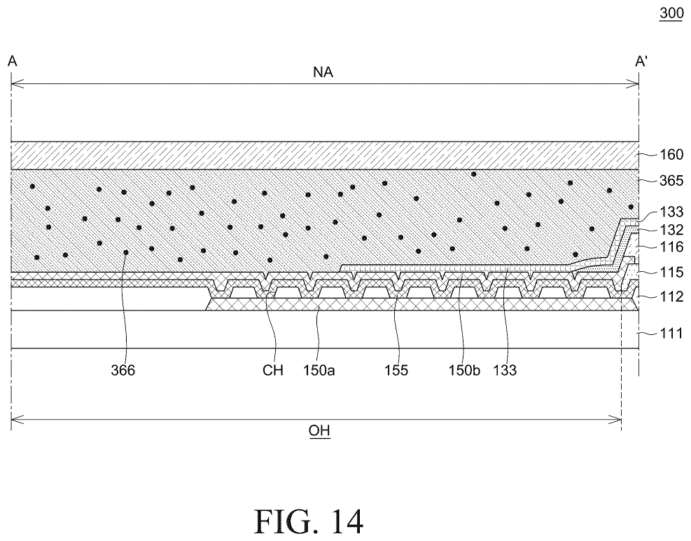

FIG. 14 is a cross-sectional view of a display device according to a third embodiment of the present disclosure.

The third embodiment shown in FIG. 14 is substantially the same as the second embodiment shown in FIG. 9 through FIG. 13 except that adsorption particles 366 are additionally included in the adhesive layer 365. Therefore, repeated descriptions of the identical components will be omitted. The same components will be denoted by the same reference numerals. Hereinafter, description of components denoted by the same reference numerals may refer to FIG. 1 through FIG. 13.

FIG. 14 is a cross-sectional view illustrating a part of an upper non-display area NA, specifically, a part including the open hole OH, in the display device 300 according to the third embodiment of the present disclosure.

Referring to FIG. 14, an encapsulation substrate 160 may be disposed on the cathode 233 with the adhesive layer 365 interposed therebetween.

In this case, according to the third embodiment of the present disclosure, the adhesive layer 365 may further include the adsorption particles 366.

The adsorption particles 366 may be composed of fine particles capable of capturing (adsorbing) oxygen. Accordingly, the adsorption particles 366 may block diffusion of oxygen by directly adsorbing oxygen introduced from the outside and penetrating into the display device 300.

The adsorption particles 366 may include a getter material. For example, the getter material may include calcium oxide (CaO).

For example, the adsorption particles 366 may include a reduced metal oxide (MOn-x) such as reduced cerium oxide (CeO2-x).

For example, cerium oxide (CeO2-x) has a blue black color, but when oxygen is adsorbed, the color may change to light gray.

In this way, when the metal oxide (MOn-x) is reduced to make a hole (vacancy) of the oxygen defect, it is possible to absorb oxygen by reacting with oxygen of the outside air.

The exemplary embodiments of the present disclosure can also be described as follows:

A display device according to an exemplary embodiment of the present disclosure includes a substrate including a display area and a non-display area, an insulating layer and a planarization layer disposed over the substrate and extending to the non-display area, at least one trench disposed in the non-display area and confined by removing at least one of the insulating layer and the planarization layer, a bank disposed on the planarization layer and extending to the non-display area, an organic layer disposed on the bank, a cathode disposed on the organic layer, disposed on the cathode, a protective layer extending to the non-display area, and an encapsulation structure disposed on the protective layer, in which the protective layer extends outward from an end of the encapsulation structure on four sides except for a part of the non-display area, and the planarization layer and the bank may not extend outward of the trench.

According to another aspect of the present disclosure, the display device may further include a data pad part disposed on the one side of the non-display area, a gate pad part disposed on the other side of the non-display area, and a plurality of open holes confined by removing the planarization layer from the portion of the one side of the non-display area.

According to yet another aspect of the present disclosure, the display device may further include a gate-in-panel (GIP) circuit portion disposed in the gate pad part, and the GIP circuit portion may be located inside more than the trench.

According to yet another aspect of the present disclosure, the cathode may contact the top surface of the insulating layer in the trench.

According to yet another aspect of the present disclosure, the trench may include a first trench disposed over three sides of the non-display area excluding one side of the non-display area, and a second trench positioned further inward than the first trench and disposed over four sides of the non-display area.

According to yet another aspect of the present disclosure, the first trench may be configured by removing a partial area of the insulating layer and the planarization layer in the non-display area, and the second trench may be configured by removing a partial area of the planarization layer in the non-display area.

According to yet another aspect of the present disclosure, a plurality of second trenches may be disposed, and a plurality of dams configured as the planarization layer may be disposed between the plurality of second trenches.

According to yet another aspect of the present disclosure, the display device may further include a first line disposed over a part of the substrate at the one side of the non-display area, and a buffer layer disposed over the first line and patterned into an island shape in an area where the open hole is located.

According to yet another aspect of the present disclosure, a plurality of contact holes may be formed in the buffer layer to expose a top surface of the first line.

According to yet another aspect of the present disclosure, the display device further includes a low potential driving voltage line disposed on the buffer layer, and in an area in which the open hole is located, the low potential driving voltage line may be electrically connected to the first line through the contact hole.

According to yet another aspect of the present disclosure, the display device may further include a second line disposed on the low potential driving voltage line and a connection electrode disposed on a connection part at both upper ends of the open hole when viewed in a plan view, the second line may be connected to the connection electrode.

According to yet another aspect of the present disclosure, the cathode may extend into the open hole to cover a part of a top surface of the second line in the open hole, and the cathode may be in contact with the top surface of the second line.

According to yet another aspect of the present disclosure, the protective layer may have a thickness of 50% to 75% of a thickness in the display area in the taper of the trench.

According to yet another aspect of the present disclosure, the encapsulation structure includes an adhesive layer on the cathode and an encapsulation substrate, and the adhesive layer may further include adsorption particles.

According to yet another aspect of the present disclosure, the adsorbent particles may include reduced metal oxide (MOn-x).

A display device according to another exemplary embodiment of the present disclosure includes a substrate including a display area and a non-display area having four sides disposed to surround the display area, a first trench disposed over three sides excluding one side of the non-display area and confined by removing a portion of an insulating layer and a planarization layer, a second trench confined by removing the planarization layer and a plurality of open holes confined by removing the planarization layer from the outside of the second trench at the one side of the non-display area, in which the planarization layer does not extend to the outside of the second trench.

According to another aspect of the present disclosure, the display device may further include a bank disposed on the planarization layer and extending to the non-display area, the bank may not extend to the outside of the trench, but may be disposed inside the trench.

According to yet another aspect of the present disclosure, the display device may further include a protective layer disposed on the bank and extending to the non-display area, and an encapsulation structure disposed over the protective layer.

According to yet another aspect of the present disclosure, the protective layer may extend outward from an end of the encapsulation structure in the non-display area of the four sides excluding a portion of the one side of the non-display area.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a display area and a non-display area;
an insulating layer and a planarization layer disposed over the substrate and extending to the non-display area;
at least one trench disposed in the non-display area and confined by removing at least one of the insulating layer and the planarization layer;
a bank disposed on the planarization layer and extending to the non-display area;
an organic layer disposed on the bank;
a cathode disposed on the organic layer and extending to the trench;
a protective layer disposed on the cathode and extending to the non-display area; and
an encapsulation structure disposed on the protective layer,
wherein the protective layer extends outward from an end of the encapsulation structure on four sides excluding a portion of one side of the non-display area, and the planarization layer and the bank do not extend outward of the trench.

2. The display device according to claim 1, further comprising:
a data pad part disposed on the one side of the non-display area;
a gate pad part disposed on the other side of the non-display area; and
a plurality of open holes confined by removing the planarization layer from the portion of the one side of the non-display area.

3. The display device according to claim 2, further comprising:
a gate-in-panel (GIP) circuit portion disposed in the gate pad part,
wherein the GIP circuit portion is located inside the trench.

4. The display device according to claim 1, wherein the cathode is in contact with a top surface of the insulating layer in the trench.

5. The display device according to claim 2, wherein the trench includes:
a first trench disposed over three sides of the non-display area excluding one side of the non-display area; and
a second trench positioned further inward than the first trench and disposed over four sides of the non-display area.

6. The display device according to claim 5, wherein the first trench is configured by removing a partial area of the insulating layer and the planarization layer of the non-display area, and
wherein the second trench is configured by removing a partial area of the planarization layer of the non-display area.

7. The display device according to claim 6, wherein a plurality of second trenches are disposed, and
wherein a plurality of dams configured as the planarization layer are disposed between the plurality of second trenches.

8. The display device according to claim 2, further comprising:
a first line disposed over a part of the substrate at the one side of the non-display area; and
a buffer layer disposed over the first line and patterned into an island shape in an area where the open hole is located.

9. The display device according to claim 8, wherein a plurality of contact holes are formed in the buffer layer to expose a top surface of the first line.

10. The display device according to claim 9, further comprising:
a low potential driving voltage line disposed on the buffer layer,
wherein, in the area in which the open hole is located, the low potential driving voltage line is electrically connected to the first line through the contact hole.

11. The display device according to claim 10, further comprising:
a second line disposed on the low potential driving voltage line; and
a connection electrode disposed on a connection part at both upper ends of the open hole when viewed in a plan view,
wherein the second line is connected to the connection electrode.

12. The display device according to claim 11, wherein the cathode is extended into the open hole to cover a part of a top surface of the second line in the open hole, and
wherein the cathode is in contact with the top surface of the second line.

13. The display device according to claim 1, wherein the protective layer has a thickness of 50% to 75% of a thickness in the display area in a taper of the trench.

14. The display device according to claim 1, wherein the encapsulation structure includes an adhesive layer over the cathode and an encapsulation substrate, and
wherein the adhesive layer further includes adsorbent particles.

15. The display device according to claim 14, wherein the adsorbent particles include a reduced metal oxide (MOn-x).

16. A display device, comprising:
a substrate including a display area and a non-display area having four sides disposed to enclose the display area;
a first trench disposed over three sides excluding one side of the non-display area and configured by removing a portion of an insulating layer and a planarization layer;
a second trench disposed over the non-display area on the four sides from an inner side of the first trench and configured by removing the planarization layer; and
a plurality of open holes configured by removing the planarization layer from an outer side of the second trench on the one side of the non-display area,
wherein the planarization layer does not extend to the outer side of the second trench and is disposed inside the trench.

17. The display device according to claim 16, further comprising:
a bank disposed on the planarization layer and extending to the non-display area,
wherein the bank does not extend to the outside of the trench, but is disposed inside the trench.

18. The display device according to claim 17, further comprising:
a protective layer disposed on the bank and extending to the non-display area; and
an encapsulation structure disposed over the protective layer.

19. The display device according to claim 18, wherein the protective layer extends outward from an end of the encapsulation structure in the non-display area of the four sides excluding a portion of the one side of the non-display area.
